(19) United States
(12) Patent Application Publication
(10) Pub. No.: US 2008/0157189 A1
(43) Pub. Date: Jul. 3, 2008

(54) Power Semiconductor Device

(76) Inventors: Young Won Lee, Incheon-Si (KR); Moon Soo Cho, Seoul (KR)

Correspondence Address: IPHORGAN, LTD., 1130 LAKE COOK ROAD, SUITE 240, BUFFALO GROVE, IL, 60089, US

(21) Appl. No.: 11/884,251

(22) PCT Filed: Oct. 25, 2005
(86) PCT No.: PCT/KR2005/003552

§ 371 Date: Aug. 13, 2007

(30) Foreign Application Priority Data
Feb. 14, 2005 (KR) 10-2005-0011774

(51) Int. Cl. H01L 29/78

(52) U.S. Cl. 257/329; 257/E29.262

(57) ABSTRACT

Disclosed is a power semiconductor device capable of transmitting a gate signal from any upward, downward, leftward, and rightward directions on a plane to reduce deviation in the gate signal's transmission speed and impedance. The power semiconductor device includes a conductive low-density epitaxial layer; a first conductive region having a number of first conductive layers formed linearly on the surface of the epitaxial layer with predetermined spacing and depth and a number of second conductive layers formed linearly with a predetermined spacing while being spaced a predetermined distance from ends of the first conductive >layers; a second conducive region formed with a width and a depth smaller than those of the first and second conductive layers so that channels can be formed on the first and second conductive layers, respectively; gate oxide having a first window formed on the surface of the epitaxial layer with a width smaller than that of the first conductive layers and a second window formed with a width smaller than that of the second conductive layers; and gate polysilicon formed on the gate oxide.

### TECHNICAL FIELD

The present invention relates to a power semiconductor device, and more particularly to a power semiconductor device capable of transmitting a gate signal from any upward, downward, leftward, and rightward directions on a plane to reduce deviation in the gate signal's transmission speed and impedance.

### BACKGROUND ART

In general, power semiconductor devices (for example, power MOSFETs or IGBTs) are manufactured in a trench or planar type. Planar-type power semiconductor devices are used for switching-mode power supplies, DC-DC converters, electronic stabilizers for fluorescent lamps, and inverters for motors. They need to have small switching loss and conduction loss and sufficiently high yield voltage. By using these devices, it is possible to reduce the size of final products due to increased energy efficiency and decreased heat. The planar-type power semiconductor devices are classified into closed-cell-type devices and stripe-type devices.

As shown in FIGS. 1a and 1d, a closed-cell-type power semiconductor device has a number of P type first conductive regions 130′ formed on the surface of an N type epitaxial layer 120′ as separate cells with a predetermined spacing and N type second conductive regions 140′ formed in the respective first conductive regions 130′ as cells. Gate oxide 150′ and gate polysilicon 160′ are formed on the surface of the N type epitaxial layer 120′ with a predetermined thickness in such a manner that a window 151′ is provided in each P type first conductive region 130′. Although not shown in the drawings, gate metal is connected to the gate polysilicon 160′ at a specific part of the device, which is referred to as a gate pad. Source metal is connected to the P type first conductive region 130′ and the N type second conductive region 140′. Drain metal is connected to the lower portion of the N type epitaxial layer 120′ (to that of the N type semiconductor substrate). When a predetermined voltage is applied to the gate polysilicon 160′ in the closed-cell-type power semiconductor device, constructed as above, horizontal channels are established in the P type first conductive regions 130′ between the N type second conductive regions 140′ and the N type epitaxial layer 120′. As a result, a current flows from the drain to the source, or vice versa.

The closed-cell-type semiconductor device has a problem in that, since the junctions between the P type first conductive regions 130′ and the N type epitaxial layer 120′ have a shape similar to that of a spherical surface, Avalanche break-down voltage decreases in the active region. In addition, the gate polysilicon 160′ and the N type epitaxial layer 120′ (drain-side drift region) face each other over a large area. This increases Miller capacitance and decreases switching speed. When high dV_{DS}/dt is applied, erroneous operation easily occurs.

As shown in FIGS. 2a and 2d, a stripe-type power semiconductor device has a number of P type first conductive regions 230′ formed on the surface of an N type epitaxial layer 220′ as stripes with a predetermined spacing and N type second conductive regions 240′ formed in the respective P type first conductive regions 230′ as stripes with a predetermined depth. Gate oxide 250′ and gate polysilicon 260′ are formed on the surface of the N type epitaxial layer 220′ with a predetermined thickness in such a manner that a window 251′ is provided as a stripe in each P type first conductive region 230′. Although not shown in the drawings, gate metal is connected to the gate polysilicon 260′ at a specific part of the device, which is referred to as a gate pad. Source metal is connected to the P type first conductive region 230′ and the N type second conductive region 240′. Drain metal is connected to the lower portion of the N type epitaxial layer 220′. When a predetermined voltage is applied to the gate in the stripe-type power semiconductor device, constructed as above, horizontal channels are established in the P type first conductive regions 230′ between the N type second conductive regions 240′ and the N type epitaxial layer 220′. As a result, a current flows from the drain to the source, or vice versa.

The stripe-type power semiconductor device is advantageous in that, since the junctions between the P type first conductive regions 230′ and the N type epitaxial layer 220′ have a shape similar to that of a cylindrical surface, Avalanche break-down voltage increases in the active region. In addition, the gate polysilicon 260′ and the N type epitaxial layer 220′ (drain-side drift region) face each other over a small area. This decreases Miller capacitance and increases switching speed. When high dVDS/dt is applied, erroneous operation hardly occurs. Therefore, stripe-type power semiconductor devices have recently been manufactured, sold, and used in many cases.

In the case of the closed-cell-type power semiconductor device, referring to FIG. 1a, gate signals are transmitted to the first and second conductive regions 130′ and 140′ from any upward, downward, leftward, and rightward directions on the drawing. In the case of the stripe-type power semiconductor device, in contrast, referring to FIG. 2a, gate signals are transmitted to the polysilicon 260′ from upward or downward direction on the drawing. This results in serious deviation in the transmission speed of the gate signals and the impedance to the gate driver circuit, depending on a specific part of the entire device.

Consequently, although not shown in the drawings, a large number of gate bus lines must be positioned midway through the stripe-type power semiconductor device using the same material as the source metal to connect the gate polysilicon 260′. As a result, area loss occurs and the source current fails to flow smoothly. This degrades the device characteristics.

Although problems occurring in the prior art have been described with reference to an N type semiconductor device (i.e., N channel type MOSFET), the same problems occur in the case of a P type semiconductor device (i.e., P channel type MOSFET) and repeated description thereof will be omitted.

### DISCLOSURE OF THE INVENTION

Therefore, the present invention has been made in view of the above-mentioned problems, and it is an object of the present invention to provide a power semiconductor device having P type first conductive regions formed as stripes and capable of transmitting a gate signal from any upward, downward, leftward, and rightward directions on a plane to reduce deviation in the gate signal's transmission speed and impedance.

Another object of the present invention is to provide a power semiconductor device having a large channel width to avoid concentration of electric field and reduce resistance between drain and source (R_{ds(ON)}).

In order to accomplish these objects, there is provided a power semiconductor device including a conductive low-density epitaxial layer; a first conductive region having a number of first conductive layers formed linearly on the surface of the epitaxial layer with predetermined spacing and depth and a number of second conductive layers formed linearly with a predetermined spacing while being spaced a predetermined distance from ends of the first conductive layers; a second conducive region formed with a width and a depth smaller than those of the first and second conductive layers so that channels can be formed on the first and second conductive layers, respectively; gate oxide having a first window formed on the surface of the epitaxial layer with a width smaller than that of the first conductive layers and a second window formed with a width smaller than that of the second conductive layers; and gate polysilicon formed on the gate oxide.

The epitaxial layer may be doped with any one chosen from N− type impurities and P− type impurities.

The first conductive region may be doped with any one chosen from P type impurities and N type impurities.

The second conductive region may be doped with any one chosen from N type impurities and P type impurities.

The power semiconductor device may further include a semiconductor substrate positioned on the lower portion of the epitaxial layer and doped with any one chosen from N type impurities and P type impurities and drain metal deposited on the lower surface -of the semiconductor substrate.

The power semiconductor device may further include an insulation layer formed on the surface of the gate oxide and the gate polysilicon and source metal deposited in the first and second conductive regions which are exposed via the insulation layer.

The ends of the first and second conductive layers may face each other while alternating with each other.

The ends of the first and second conductive layers may be aligned on different straight lines while alternating with each other.

The ends of the first and second conductive layers may be aligned on the same straight line while alternating with each other.

The ends of the first and second conductive layers may extend past a straight line and overlap each other over a predetermined length while alternating with each other.

The ends of the first and second conductive layers may face each other while alternating with each other and have a semi-circular shape on a plane.

The gate polysilicon may be formed in an S-shape on a plane by means of the first and second windows.

The ends of the first and second windows may be aligned on different straight lines while facing and alternating with each other.

The ends of the first and second windows may be aligned on the same straight line while facing and alternating with each other.

The ends of the first and second windows may extend past a straight line and overlap each other over a predetermined length while facing and alternating with each other.

The epitaxial layer may be formed by successively growing an N+ type semiconductor and an N− type semiconductor on a P++ type semiconductor substrate.

The epitaxial layer may be formed by successively growing a P+0 type semiconductor and a P− type semiconductor on an N++ type semiconductor substrate.

The power semiconductor device according to the present invention is advantageous in that, as the first conductive regions include first and second conductive layers with their ends facing each other while alternating with each other, a gate signal can be transmitted from any direction on a plane. Therefore, the gate signal's transmission speed to each first conductive region improves and the deviation in impedance to the external gate's driving circuit decreases.

Since the second conductive regions face the epitaxial layer (drift region) over a relatively uniform region about the first conductive regions, current is not concentrated in a specific region but is distributed uniformly. This prevents the device from degrading.

As the channel width increases by about 1.5 times in regions where the spherical junctions face the gate oxide, the overall R_{DS(ON)} decreases.

Since the gate polysilicon extends between the respective first conductive regions along an approximately S-shaped path, the number of gate bus lines is minimized, and so is the area loss. In addition, flow of the source current improves.

### BRIEF DESCRIPTION OF THE DRAWINGS

The foregoing and other objects, features and advantages of the present invention will become more apparent from the following detailed description when taken in conjunction with the accompanying drawings in which:

FIG. 1a is a partial top view showing a closed-cell-type power semiconductor device according to the prior art;

FIG. 1b is a sectional view taken along line 1-1 of FIG. 1a;

FIG. 1c is a sectional view taken along line 2-2 of FIG. 11a;

FIG. 1d is a top view showing only the top portion of the semiconductor device shown in FIG. 1a;

FIG. 2a is a partial top view showing a stripe-type power semiconductor device according to the prior art;

FIG. 2b is a sectional view taken along line 3-3 of FIG. 2a;

FIG. 2c is a sectional view taken along line 4-4 of FIG. 2a;

FIG. 2d is a top view showing only the top portion of the semiconductor device shown in FIG. 2a;

FIG. 3a is a partial top view showing a power semiconductor device according to the present invention;

FIG. 3b is a sectional view taken along line 5-5 of FIG. 3a;

FIG. 3c is a sectional view taken along line 6-6 of FIG. 3a;

FIG. 3d is a top view showing only the top portion of the semiconductor device shown in FIG. 3a;

FIG. 4 is a sectional view showing a power semiconductor device according to the present invention, which has source metal and drain metal formed thereon;

FIG. 5a is a partial top view showing a power semiconductor device according to another embodiment of the present invention;

FIG. 5b is a top view showing only the top portion of the semiconductor device shown in FIG. 5a;

FIG. 6 is a sectional view showing a power semiconductor device according to another embodiment of the present invention; and

FIGS. 7a to 7d are diagrammatic views showing a series of steps of a method for manufacturing a power semiconductor device according to the present invention.

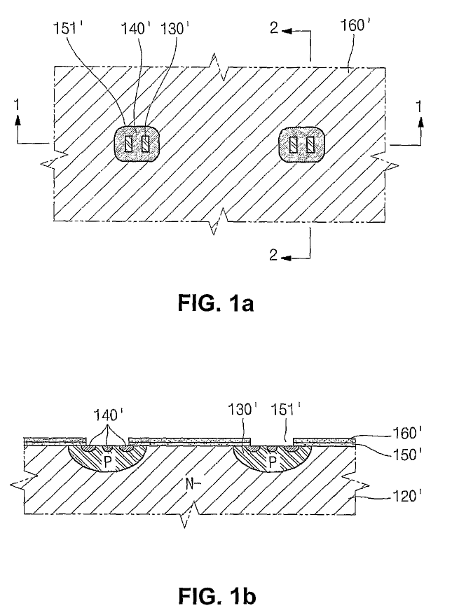

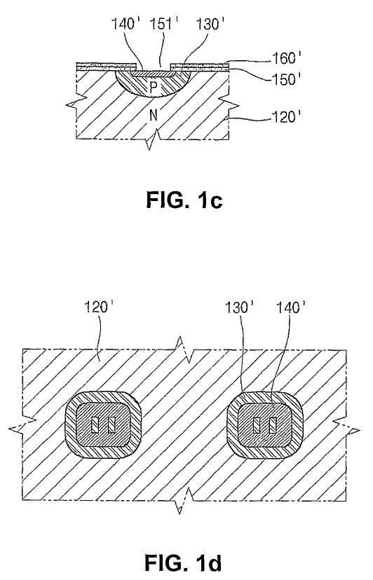

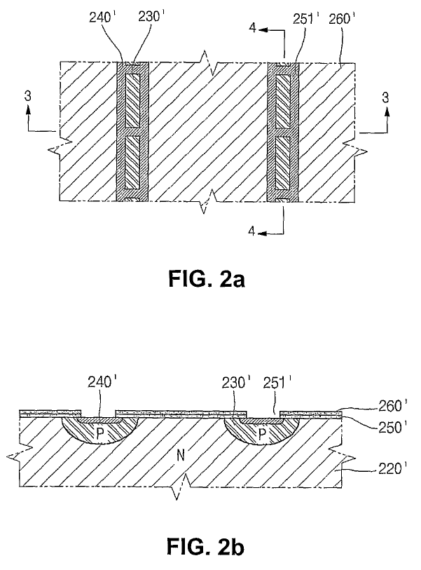

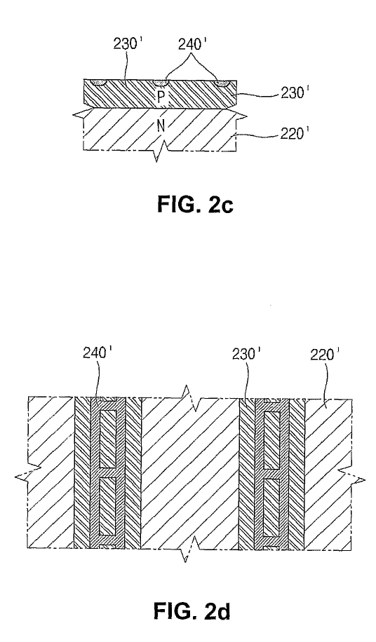

### BEST MODE FOR CARRYING OUT THE INVENTION

Reference will now be made in detail to the preferred embodiments of the present invention.

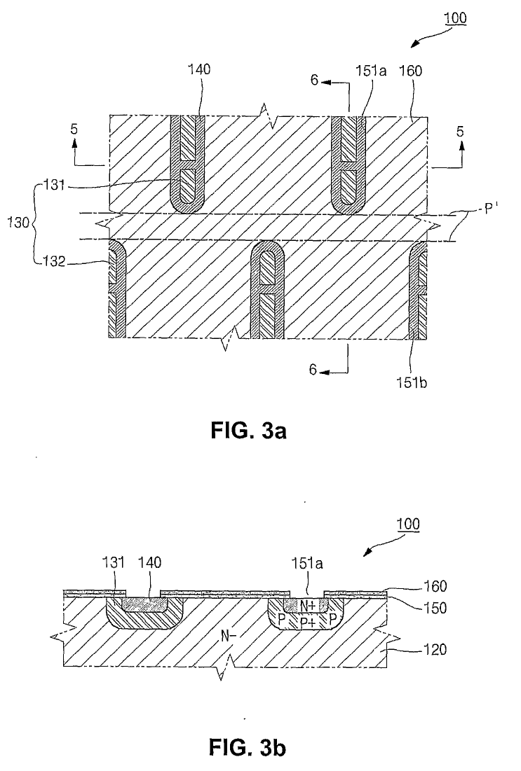

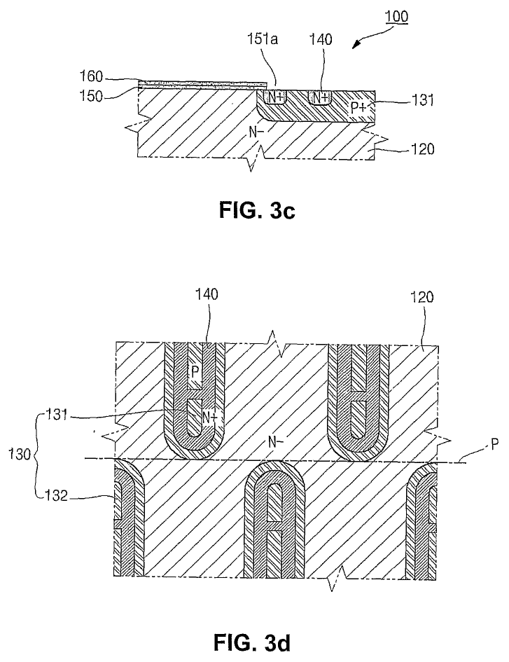

Referring to FIG. 3a, a partial top view showing a power semiconductor device according to the present invention is illustrated; referring to FIG. 3b, a sectional view taken along line 5-5 of FIG. 3a is illustrated; referring to FIG. 3c, a sectional view taken along line 6-6 of FIG. 3a is illustrated; and, referring to FIG. 3d, a top view showing only the top portion of the semiconductor device shown in FIG. 3a is illustrated.

As shown, the power semiconductor device 100 according to the present invention includes an epitaxial layer 120, a number of first conductive regions 130 formed on the surface of the epitaxial layer 120 with a predetermined spacing; second conductive regions 140 formed in the respective first conductive regions 130; gate oxide 150 formed on the surface of the epitaxial layer 120 in such a manner that a window is provided in each first conductive region 130, and gate polysilicon 160 formed on the gate oxide 150.

The epitaxial layer 120 is formed on a semiconductor substrate (not shown) with a predetermined thickness. The semiconductor substrate may be a silicon substrate having N type or P type impurities injected therein with high density and may have a thickness of about 50-400 μm. The epitaxial layer 120 may be a silicon layer having N type or P type impurities injected therein with lower density and may have a thickness of about 3-150 μm.

The first conductive regions 130 include a number of first and second conductive layers 131 and 132 formed linearly on the surface of the epitaxial layer 120 with a predetermined spacing. More particularly, the first and second conductive layers 131 and 132 are arranged with the same spacing while alternating with each other. Specifically, lines extending from the second conductive layers 132 are positioned at the centers of the pitch of the first conductive layers 131, or lines extending from the first conductive layers 131 are positioned at the centers of the pitch of the second conductive layers 132 (i.e., the second conductive layers 132 are shifted approximately half the pitch of the first conductive layers 131). In other words, each first conductive layer 131 has two second conductive layers 132 extending from locations spaced from an end thereof in both diagonal directions. Ends of the first and second conductive layers 131 and 132 alternative with each other and are aligned on a virtual straight line P. In addition, ends of the first and second conductive layers 131 and 132, which face each other alternately, have a semi-circular shape on a plane so that current is not concentrated in a specific region when the device is operated. The first and second conductive layers 131 and 132 have an approximately semi-cylindrical shape from a stereoscopic view other than their ends, which have an approximately ¼ spherical shape.

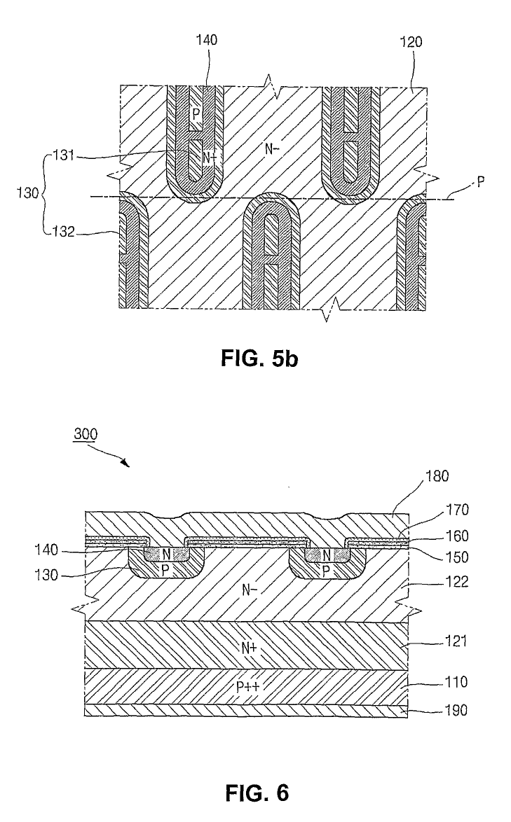

Although ends of the first and second conductive layers 131 and 132 are shown in FIG. 3d to be aligned on a common virtual straight line P, they may be respectively aligned on two different virtual straight lines (not shown). Alternatively, they may extend past a common virtual straight line P and overlap each other (refer to FIG. 5b).

The first and second conductive layers 131 and 132 may have P type or N type impurities injected therein and may have a thickness of about 1-5 μm, but the numerical value is not limited in the present invention. Approximately central portion of the first and second conductive layers 131 and 132 may have higher density and approximately peripheral portion thereof lower density.

The second conductive regions 140 are formed on the first and second conductive layers 131 and 132 with a predetermined depth, respectively. Particularly, the width and depth of the second conductive regions 140 are smaller than those of the first and second conductive layers 131 and 132.

The second conductive regions 140 may have N type or P type impurities injected therein with high density and may have a thickness of about 1 μm or less, but the numerical value is not limited in the present invention.

In this structure, channels may be formed on the surface of the first conductive regions 130, which correspond to the outer peripheral edge of the second conductive regions 140, so that carriers (for example, electrons) can pass through.

The gate oxide 150 is generally formed on the surface of the epitaxial layer 120 in such a manner that first windows 151 a are formed with a width smaller than that of the first conductive layers 131 and second windows 151b are formed with a width smaller than that of the second conductive layers 132. Particularly, the first windows 151a cover parts of the second conductive regions 140 formed inside the first conductive layers 131 and the second windows 152b cover parts of the second conductive regions 140 formed inside the second conductive layers 132. The gate oxide 150 may have a thickness of about 200-1000 Å, but the numerical value is not limited in the present invention.

The gate polysilicon 160 is formed on the gate oxide 150. Since the gate polysilicion 160 is formed only on the gate oxide 150, the second conductive regions 140 are exposed to the exterior via the first and second windows 151a and 151b. The gate polysilicon 160 is doped with conductive impurities (for example, N type or P type impurities) so that it can act as a gate.

The gate polysilicon 160 is formed in an approximate S-shape on a plane by means of the arrangement of the first and second windows 151a and 151 b. This is because, although ends of the first and second conductive layers 131 and 132 are aligned on a single virtual straight line, ends of the first and second windows 151a and 151b formed thereon are aligned on two different virtual straight lines P′, not on a single straight line. In other words, the gate polysilicon 160 extends between the first and second windows 151a and 151b along an approximately S-shaped path.

Although ends of the first and second windows 151a and 151b are shown in FIG. 3a to be respectively aligned on two virtual straight lines P′, they may be aligned on the same virtual straight line P′ (refer to FIG. 5a). Alternatively, they may extend past a common virtual straight line and overlap each other (not shown).

It is obvious to those skilled in the art that, although a small number of first and second conductive regions 130 and 140 are shown in the drawings, hundreds or millions of first and second conductive regions 130 and 140 may be integrated on a single semiconductor die.

According to the present invention, gate signals can be applied to the first conductive regions 130, particularly to the first and second conductive layers 131 and 132, from any upward, downward, leftward, and rightward directions on a plane without any separate gate bus line for connecting the gate polysilicon, which is spaced in the vertical direction, as in the prior art. Particularly, the gate polysilicon 160 extends between the first and second conductive layers 131 and 132 along an approximately S-shaped path on a plane so that a gate signal can be applied to each of the first and second conductive layers 131 and 132 from any upward, downward, leftward, and rightward directions.

In addition, the epitaxial layer 120 (drift region) appear larger in the second conductive regions 140 outside the first conductive regions 130 (i.e., first or second conductive layers 131 or 132) and are relatively uniform, so that current concentration does not occur when the device is operated. The width of channels formed on the surface of the first conductive regions 130 (i.e., first or second conductive regions 131 or 132) outside the second conductive regions 140 is about 1.5 times larger than that of the cylindrical junctions, where the spherical junctions of the ends face the gate oxide. This improves the overall R_{DS(ON)} or V_{CE(SAT)}.

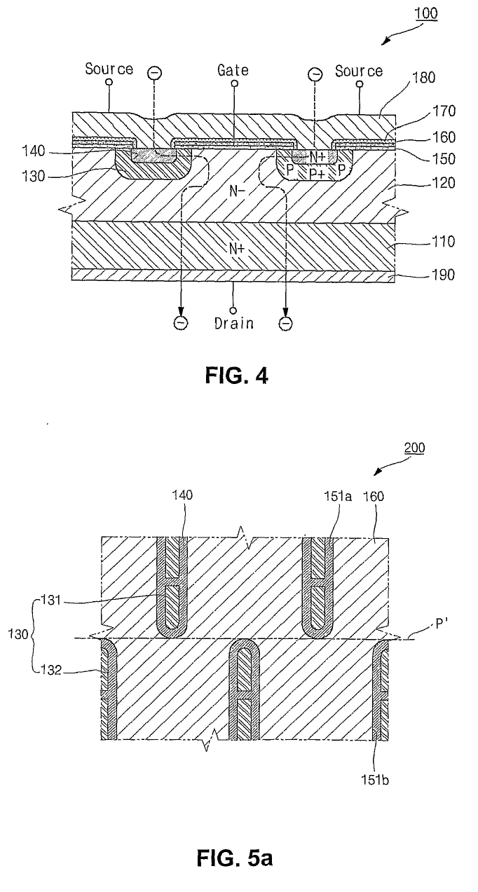

Referring to FIG. 4, a sectional view showing the power semiconductor device according to the present invention, which has source metal and drain metal formed thereon, is illustrated. The operation of the device will now be described briefly with reference to the drawing.

As shown, the semiconductor substrate 110 has an epitaxial layer 120 formed on the upper surface thereof and drain metal 190 formed on the lower surface thereof using gold, silver, solder, vanadium, Y aluminum, or equivalent metal thereof. The gate polysilicon 160 has an insulation layer 170 formed on the surface thereof with a predetermined thickness in such a manner that it covers the lateral surface of the gate oxide 150 and the gate polysilicon 160. The second conductive regions 140, which are exposed via the insulation layer 170, have source metal 180 formed on the surface thereof with a predetermined thickness using aluminum or equivalent metal thereof. The source metal 180 connects all second conductive regions 140 together. Although not shown in the drawing, the gate polysilicon 160 has gate metal connected thereto at a specific part of the device.

When a voltage of a predetermined value or higher is applied to the gate metal (not shown) and a voltage is also applied to the source metal 180 and the drain metal 190, a predetermined amount of current flows from the drain metal 190 towards the source metal 180. Particularly, channels are established on the surface of the first conductive regions 130 outside the second conductive regions 140 due to the voltage applied to the gate metal. Consequently, electrons flow from the source metal 180 to the drain metal 190 via the second conductive regions 140, the channels formed in the first conductive regions 130, the epitaxial layer 120 (drift region), and the semiconductor substrate 110.

Meanwhile, a semiconductor device including an N+type semiconductor substrate, an N− type epitaxial layer, P type first conductive regions, and N type second conductive regions, as mentioned above and shown in the drawings, may also be referred to as an N channel type MOSFET. In addition to the N channel type MOSFET, the present invention can be directly applied to a P channel type MOSFET, which includes a P type semiconductor substrate, a P type epitaxial layer, N type first conductive regions, and P type second conductive regions.

In addition, the present invention is directly applicable to IGBTs, besides the MOFSETs.

Specifically, the above-mentioned arrangement of the first conductive regions and the windows according to the present invention can be directly applied to an N channel IGBT, which includes a P+ type semiconductor substrate 110, an N+ type epitaxial layer 121, an N− type epitaxial layer 122, P type first conductive regions 130, and N type second conductive regions 140, as shown in FIG. 6.

In addition, although not shown in the drawings, the above-mentioned arrangement of the first conductive regions and the windows according to the present invention can be directly applied to a P channel IGBT, which includes an N+ type semiconductor substrate, a P+ type epitaxial layer, a P− type epitaxial layer, N type first conductive regions, and P type second conductive regions.

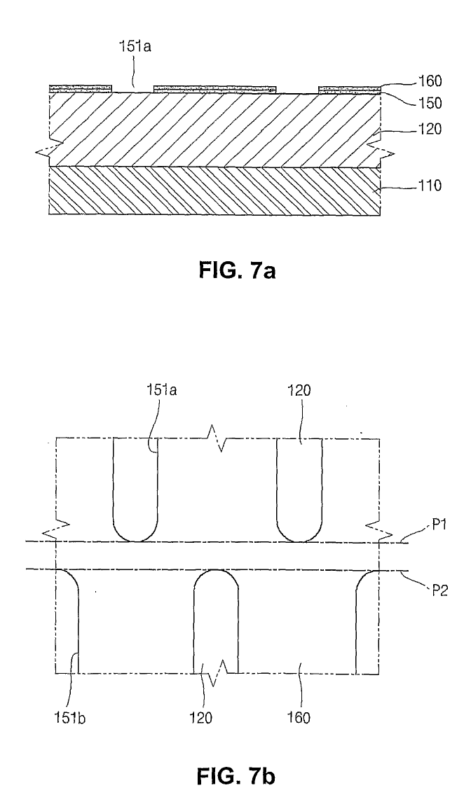

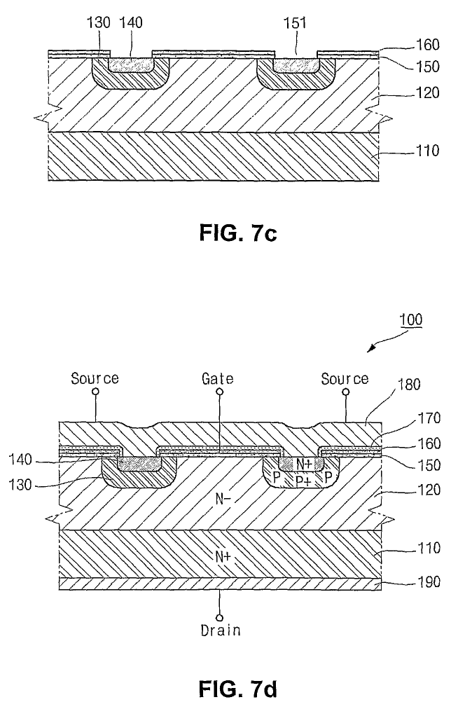

Referring to FIGS. 7a to 7d, diagrammatic views showing a series of steps of a method for manufacturing a power semiconductor device according to the present invention is illustrated.

As shown in FIG. 7a, an epitaxial layer 120 is formed on a semiconductor substrate 110 with a predetermined thickness. Then, gate oxide 150 and gate polysilicon 160 are successively formed on the epitaxial layer 120 with a predetermined thickness. After the film formation, a number of windows 151a are formed in an approximately linear shape using photolithography to expose the surface of the epitaxial layer 120 to the exterior. The planar arrangement of the windows 151a will be described later.

The semiconductor substrate 110 may be a silicon substrate having N type impurities injected therein with high density and may have a thickness of about 50-400 μm. The epitaxial layer 120 may be made of silicon having N type impurities injected therein with low density and may have a thickness of about 3-150 μm. However, the construction thereof is not limited in the present invention.

As shown in FIG. 7b, the windows formed by etching the gate oxide 150 and the gate polysilicon 160 generally include first windows 151a and second windows 151b. Specifically, a large number of first and second windows 151aand 151b may be formed in an approximately linear shape and their ends, which face each other while alternating with each other, have an approximately semi-circular shape on a plane. All ends of the first windows 151 a are aligned on a single virtual straight line P1 and those of the second windows 151b are aligned on another virtual straight line P2. The first and second windows 151a and 151b are arranged with approximately the same pitch, respectively, in such a manner that lines extending from the second windows 151 b coincide with the centers of the pitch the first windows 151a. In other words, the second windows 151b are shifted approximately half the pitch of the first windows 151a.

As shown in FIG. 7c, first and second conductive regions 130 and 140 are successively formed on the epitaxial layer 120, which is exposed via the windows 151, with a predetermined depth. For example, P type impurities, such as boron (B), are ion-injected via the windows 151 using a self-alignment method and are heat-treated at about 1100° C. or higher to form the first conductive regions 130. A separate mask is used to further ion-inject P type impurities into the central portion of the first conductive regions 130 for Ohmic contact with source metal at a later time. In addition, N type impurities, such as arsenic (As), are ion-injected and heat-treated at about 900° C. or higher to form the second conductive regions 140. In this process, the first conductive regions 130 must have a depth of about 1-5 μm and the second conductive regions 140 about 1 μm or less.

As shown in FIG. 7d, a metal deposition process is performed after forming and etching an insulation film. In particular, an insulation layer 170 is formed on the upper and lateral surfaces of the gate polysilicon 160 with a predetermined thickness and source metal 180 is formed on the second conductive regions 140, which are exposed via the insulation layer 170, using aluminum or an equivalent thereof. In addition, drain metal 190 is formed on the lower surface of the semiconductor substrate 110 using gold, silver, vanadium, aluminum, or equivalent metal thereof.

Although not shown in the drawings, gate metal is formed on the gate polysilicon 160 at a specific part of the device, which is referred to as a gate pad, using aluminum or an equivalent thereof for voltage application. A power semiconductor device 100 completed in these processes is mounted on a lead frame, etc., and is subjected to wire bonding and molding processes to finish a semiconductor package. The drain metal 190 is directly connected to a die paddle of the lead frame by solder, etc., and the source metal 180 and the gate metal are bonded to the lead frame's leads by wires, respectively.

### INDUSTRIAL APPLICABILITY

As can be seen from the foregoing, the power semiconductor device according to the present invention is advantageous in that, as the first conductive regions include first and second conductive layers with their ends facing each other while alternating with each other, a gate signal can be transmitted from any direction on a plane. Therefore, the gate signal's transmission speed to each first conductive region improves and the deviation in impedance to the external gate's driving circuit decreases.

Since the second conductive regions face the epitaxial layer (drift region) over a relatively uniform region about the first conductive regions, current is not concentrated in a specific region but is distributed uniformly. This prevents the device from degrading.

As the channel width increases by about 1.5 times in regions where the spherical junctions face the gate oxide, the overall R_{DS(ON)} decreases.

Since the gate polysilicon extends between the respective first conductive regions along an approximately S-shaped path, the number of gate bus lines is minimized, and so is the area loss. In addition, flow of the source current improves.

While this invention has been described in connection with what is presently considered to be the most practical and preferred embodiment, it is to be understood that the invention is not limited to the disclosed embodiment and the drawings, but, on the contrary, it is intended to cover various modifications and variations within the spirit and scope of the appended claims.

1. A power semiconductor device comprising:
a conductive low-density epitaxial layer;
a first conductive region having a number of first conductive layers formed linearly on the surface of the epitaxial layer with predetermined spacing and depth and a number of second conductive layers formed linearly with a predetermined spacing while being spaced a predetermined distance from ends of the first conductive layers;
a second conducive region formed with a width and a depth smaller than those of the first and second conductive layers so that channels can be formed on the first and second conductive layers, respectively;
gate oxide having a first window formed on the surface of the epitaxial layer with a width smaller than that of the first conductive layers and a second window formed with a width smaller than that of the second conductive layers; and
gate polysilicon formed on the gate oxide.

2. The power semiconductor device as claimed in claim 1, wherein the epitaxial layer is doped with any one chosen from a group comprising N− type impurities and P− type impurities.

3. The power semiconductor device as claimed in claim 1, wherein the first conductive region is doped with any one chosen from a group comprising P type impurities and N type impurities.

4. The power semiconductor device as claimed in claim 1, wherein the second conductive region is doped with any one chosen from a group comprising N type impurities and P type impurities.

5. The power semiconductor device as claimed in claim 1, further comprising a semiconductor substrate positioned on the lower portion of the epitaxial layer and doped with any one chosen from a group comprising N type impurities and P type impurities and drain metal deposited on the lower surface of the semiconductor substrate.

6. The power semiconductor device as claimed in claim 1, further comprising an insulation layer formed on the surface of the gate oxide and the gate polysilicon and source metal deposited in the first and second conductive regions which are exposed via the insulation layer.

7. The power semiconductor device as claimed in claim 1, wherein ends of the first and second conductive layers face each other while alternating with each other.

8. The power semiconductor device as claimed in claim 1, wherein ends of the first and second conductive layers are aligned on different straight lines while alternating with each other.

9. The power semiconductor device as claimed in claim 1, wherein ends of the first and second conductive layers are aligned on the same straight line while alternating with each other.

10. The power semiconductor device as claimed in claim 1, wherein ends of the first and second conductive layers extend past a straight line and overlap each other over a predetermined length while alternating with each other.

11. The power semiconductor device as claimed in claim 1, wherein ends of the first and second conductive layers face each other while alternating with each other and have a semi-circular shape on a plane.

12. The power semiconductor device as claimed in claim 1, wherein the gate polysilicon is formed in an S-shape on a plane by means of the first and second windows.

13. The power semiconductor device as claimed in claim 1, wherein ends of the first and second windows are aligned on different straight lines while facing and alternating with each other.

14. The power semiconductor device as claimed in claim 1, wherein ends of the first and second windows are aligned on the same straight line while facing and alternating with each other.

15. The power semiconductor device as claimed in claim 1, wherein ends of the first and second windows extend past a straight line and overlap each other over a predetermined length while facing and alternating with each other.

16. The power semiconductor device as claimed in claim 1, wherein the epitaxial layer is formed by successively growing an N+ type semiconductor and an N− type semiconductor on a P++ type semiconductor substrate.

17. The power semiconductor device as claimed in claim 1, wherein the epitaxial layer is formed by successively growing a P+ type semiconductor and a P− type semiconductor on an N++ type semiconductor substrate.
